(19) United States
(12) Patent Application Publication
(10) Pub. No.: US 2012/0024478 A1
(43) Pub. Date: Feb. 2, 2012

(54) Showerhead

(75) Inventors: Chien-Ping Huang, Tainan (TW); Tsan-Hua HUANG, Tainan (TW)

(73) Assignee: HERMES-EPITEK CORPORATION, TAIPEI (TW)

(21) Appl. No.: 12/846,279

(22) Filed: Jul. 29, 2010

(51) Int. Cl. H01L 21/306; B23P 15/16

(52) U.S. Cl. 156/345.34; 29/890.143

(57) ABSTRACT

A showerhead is disclosed in this invention. The showerhead includes a bottom plate, a channel plate, and a top plate. The bottom plate includes a plurality of cooling channels and a plurality of gas holes, wherein the gas holes includes at least one first gas hole and at least one second gas hole. The channel plate includes a first trench area and a second trench area, wherein the first gas hole is connected with the first trench area, and the second gas hole is connected with the second trench area. The top plate is coupled to the channel plate.

### BACKGROUND OF THE INVENTION

1. Field of the Invention

The present invention generally relates to semiconductor equipment, and more particularly to a showerhead.

2. Description of Related Art

Semiconductor manufacturing equipment is commonly used in the production of semiconductor components. The semiconductor manufacturing equipment typically has a reaction chamber. The reaction gases which are required by the semiconductor manufacturing process can be provided into the reaction chamber by the showerhead of the reaction chamber. FIG. 1 shows a sectional view of a conventional showerhead 100. The conventional showerhead 100 includes a bottom portion 110, a plurality of gas tubes 120, a first plate 131, a second plate 132, and a top portion 140. The gas tubes 120 include a plurality of first gas tubes 121 and a plurality of second gas tubes 122. Moreover, the conventional showerhead 100 includes a first space 191, a second space 192, and a third space 193. A first process gas and a second process gas can flow into the second space 192 and the third space 193 respectively. The first process gas and the second process gas can also flow into the inside of the reaction chamber through the first gas tubes 121 and the second gas tubes 122 respectively. On the other hand, the fluid which flows into the first space 191 will not flow into the inside of the reaction chamber. Therefore, cooling fluid, such as water, can flow into the first space 191 for cooling the conventional showerhead 100.

FIGS. 2A-2F show the making steps of the conventional showerhead 100 shown in FIG. 1. Referring to FIGS. 2A-2C, a bottom portion 110 and a plurality of gas tubes 120 are provided, wherein the bottom portion 110 has a plurality of openings. Then, the gas tubes 120 are inserted into the openings of the bottom portion 110. After that, a soldering process, such as a high temperature soldering process (hard soldering or brazing), is performed for fixing the gas tubes 120 on the openings of the bottom portion 110 and sealing the clearances between the gas tubes 120 and the openings. In the real case, the number of the gas tubes 120 can be thousands. Therefore, the step of inserting the gas tubes 120 into the openings of the bottom portion 110 may cost a long period of time. The quality of the conventional showerhead 100 is affected by the sealing performance of sealing the clearances between the gas tubes 120 and the openings of the bottom portion 110.

Referring to FIGS. 2D-2F, a first plate 131 and a second plate 132 are provided, wherein the first plate 131 and the second plate 132 have a plurality of openings respectively. Then, the gas tubes 120 are inserted into the openings of the first plate 131 and the second plate 132. After that, a soldering process, such as a high temperature soldering process (hard soldering or brazing), is performed for fixing the gas tubes 120 on the openings of the first plate 131 and the second plate 132. The high temperature soldering process is also performed for sealing the clearances between the gas tubes 120 and the openings of the first plate 131 and the second plate 132. Finally, the top portion 140 is provided and assembled to the bottom portion 110 so as to finish the making steps of the conventional showerhead 100.

The quality of the high temperature soldering process is very important for the conventional showerhead 100. Any one of the gas tubes 120 which is not soldered properly may cause the whole conventional showerhead 100 to fail. For example, a first process gas and a second process gas can flow into the second space 192 and the third space 193 respectively. If leakage happened between the second space 192 and the third space 193, the first process gas and the second process gas are mixed within the conventional showerhead 100. The particles which are formed by the first process gas and the second process gas may clog the gas tubes 120.

Moreover, high temperature, thermal cycling, and corrosion caused by reaction gases may damage the soldering portions for sealing the clearances between the gas tubes 120 and the openings of the bottom portion 110. The cooling fluid within the first space 191 may leak into the inside of the reaction chamber. Thus, the process yields are affected by the cooling fluid.

For the reason that there are some disadvantages of the prior art mentioned above, there exists a need to propose a novel showerhead. Different process gases will not be mixed within the showerhead. The showerhead has better ability for bearing high temperature, thermal cycling, and corrosion caused by reaction gases. The showerhead has longer lifetime, and the cooling fluid will not leak into the inside of the reaction chamber and affect the process yields.

### SUMMARY OF THE INVENTION

Accordingly, the present invention has been made in order to meet such a need described above, and it is an object of the present invention to provide a novel showerhead. The showerhead has better ability for bearing high temperature, thermal cycling, and corrosion caused by reaction gases. The showerhead has longer lifetime, and the cooling fluid will not leak into the inside of the reaction chamber and affect the process yields.

In order to achieve the above object, the present invention provides a showerhead. The showerhead includes a bottom plate, a channel plate, and a top plate. The bottom plate includes a plurality of cooling channels and a plurality of gas holes, wherein the gas holes includes at least one first gas hole and at least one second gas hole. The channel plate includes a first trench area and a second trench area, wherein the first gas hole is connected with the first trench area, and the second gas hole is connected with the second trench area. The top plate is coupled to the channel plate.

According to the showerhead of the present invention, the gas holes are formed on the bottom plate and the channel plate. There is no need to use gas tubes. Different process gases will not be mixed within the showerhead. The leakage caused by clearances between the gas tubes and the bottom portion is also avoided. Therefore, the showerhead has better ability for bearing high temperature, thermal cycling, and corrosion caused by reaction gases. Thus, the showerhead has longer lifetime, and the cooling fluid will not leak into the inside of the reaction chamber.

### BRIEF DESCRIPTION OF THE DRAWINGS

FIG. 1 shows a sectional view of a conventional showerhead;

FIGS. 2A-2F show the making steps of the conventional showerhead shown in FIG. 1;

FIG. 3A shows a sectional view of the showerhead in accordance with an embodiment of the present invention;

FIG. 3B shows a top view of an example of the channel plate shown in FIG. 3A;

FIG. 3C shows a top view of another example of the channel plate shown in FIG. 3A; and

FIGS. 4A-4D show the making steps of the showerhead shown in FIG. 3A.

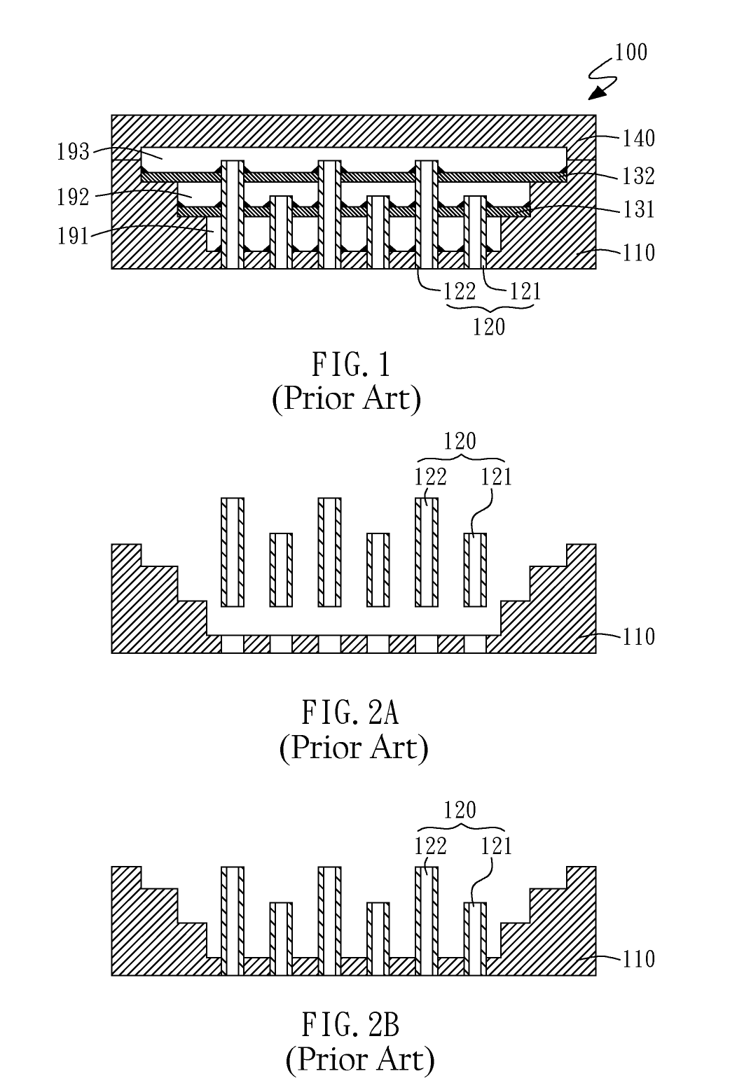

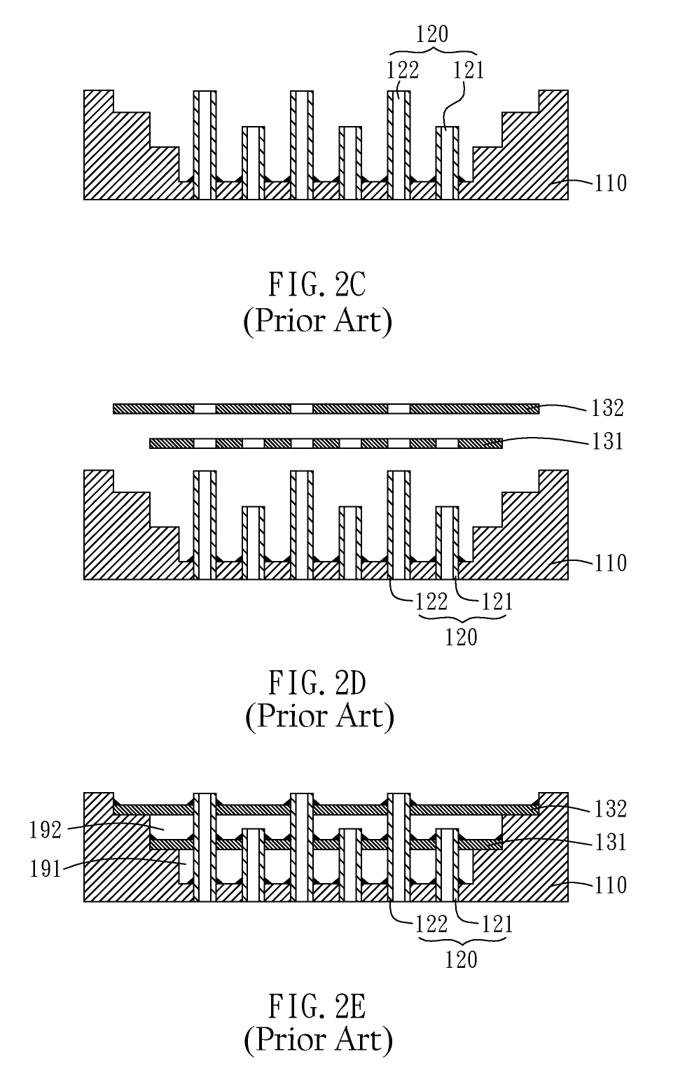

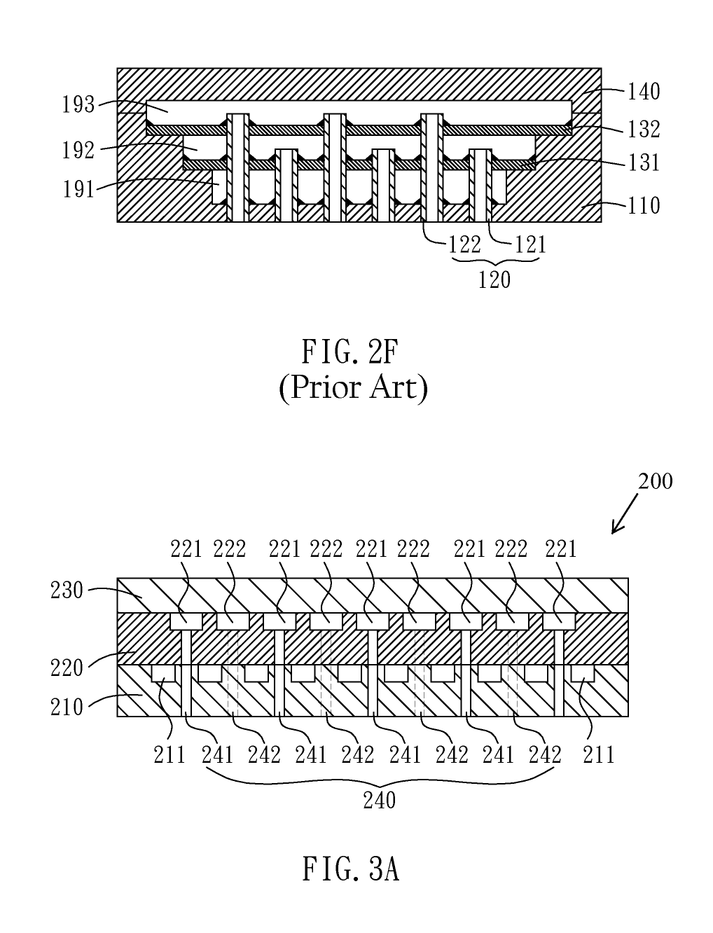

### DETAILED DESCRIPTION OF THE INVENTION

The detailed description of the present invention will be discussed in the following embodiments, which are not intended to limit the scope of the present invention, but can be adapted for other applications. While drawings are illustrated in detail, it is appreciated that the quantity of the disclosed components may be greater or less than that disclosed, except where expressly restricting the amount of the components.

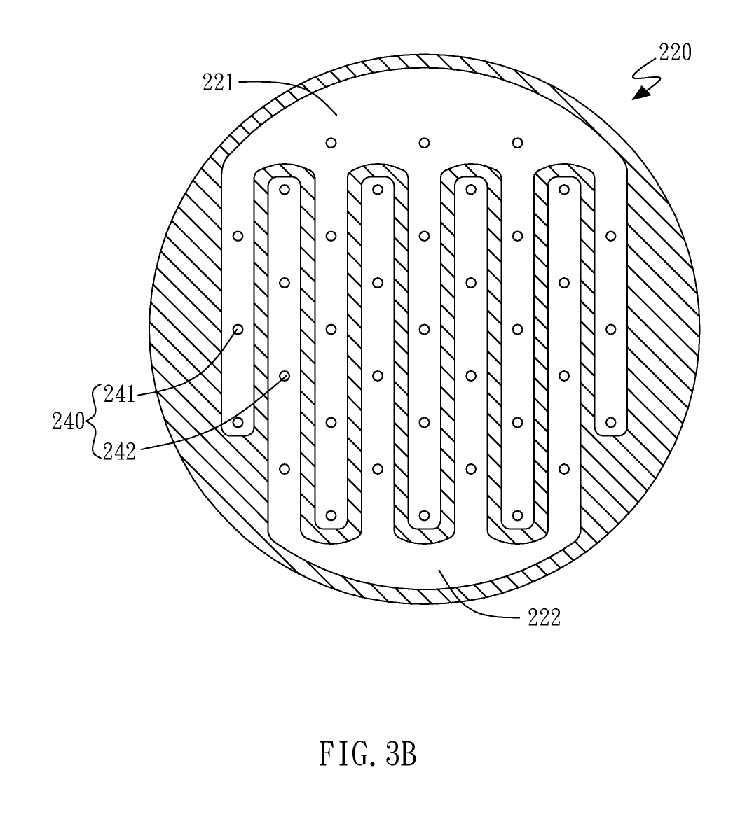

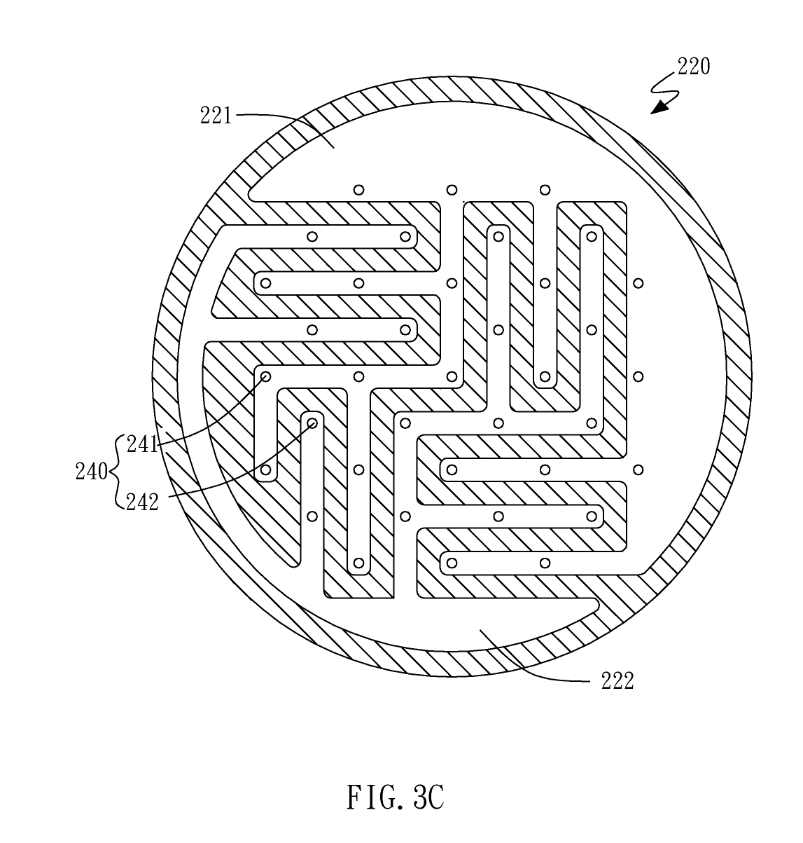

FIG. 3A shows a sectional view of a showerhead 200 in accordance with an embodiment of the present invention. The showerhead 200 includes a bottom plate 210, a channel plate 220, and a top plate 230. The bottom plate 210 includes a plurality of cooling channels 211 and a plurality of gas holes 240. The cooling fluid, such as water, can flow into the cooling channels 211 for cooling the showerhead 200. The gas holes 240 includes at least one first gas hole 241 and at least one second gas hole 242. The channel plate 220 includes a first trench area 221 and a second trench area 222. The first gas hole 241 is connected with the first trench area 221, wherein a first process gas can flow into the inside of the reaction chamber through the first trench area 221 and the first gas hole 241. The second gas hole 242 is connected with the second trench area 222, wherein a second process gas can flow into the inside of the reaction chamber through the second trench area 222 and second gas hole 242. The clearances between the bottom plate 210 and the channel plate 220 are sealed by a soldering process. The top plate 230 is coupled to the channel plate 220.

FIG. 3B shows a top view of an example of the channel plate 220 shown in FIG. 3A. The channel plate 220 includes a first trench area 221 and a second trench area 222. The first trench area 221 and the second trench area 222 are both comb-like. The first trench area 221 interlaces the second trench area 222. Furthermore, the first gas hole 241 is connected with the first trench area 221, and the second gas hole 242 is connected with the second trench area 222. The first process gas and the second process gas can flow into the inside of the reaction chamber through the first gas hole 241 and the second gas hole 242 respectively. Moreover, most of the first gas holes 241 are surrounded by the second gas holes 242. Thus, the first process gas and the second process gas can be mixed uniformly within the reaction chamber.

FIG. 3C shows a top view of another example of the channel plate 220 shown in FIG. 3A. The channel plate 220 also includes a first trench area 221 and a second trench area 222. The first gas hole 241 is connected with the first trench area 221, and the second gas hole 242 is connected with the second trench area 222. The first process gas and the second process gas can also flow into the inside of the reaction chamber through the first gas hole 241 and the second gas hole 242 respectively. In this embodiment, most of the first gas holes 241 are surrounded by the second gas holes 242. Thus, the first process gas and the second process gas can be mixed uniformly within the reaction chamber.

In this embodiment, the gas holes 240 are formed on the bottom plate 210 and the channel plate 220 by a mechanical process, wherein the mechanical process can include many kinds of processing methods, such as machining, electric discharge machining, or any other processing method. Any processing method which is capable of forming the gas holes 240 on the bottom plate 210 and the channel plate 220 is possible to be used. Different processing methods should be considered based on the real conditions. Although the mechanical process is used in this embodiment, the gas holes 240 can also be formed on the bottom plate 210 and the channel plate 220 by a chemical process or another processing method.

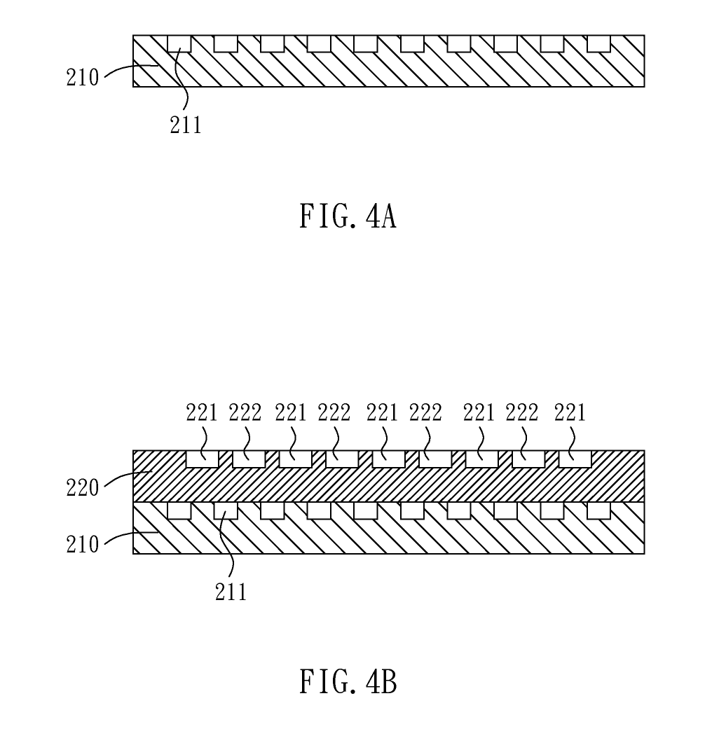

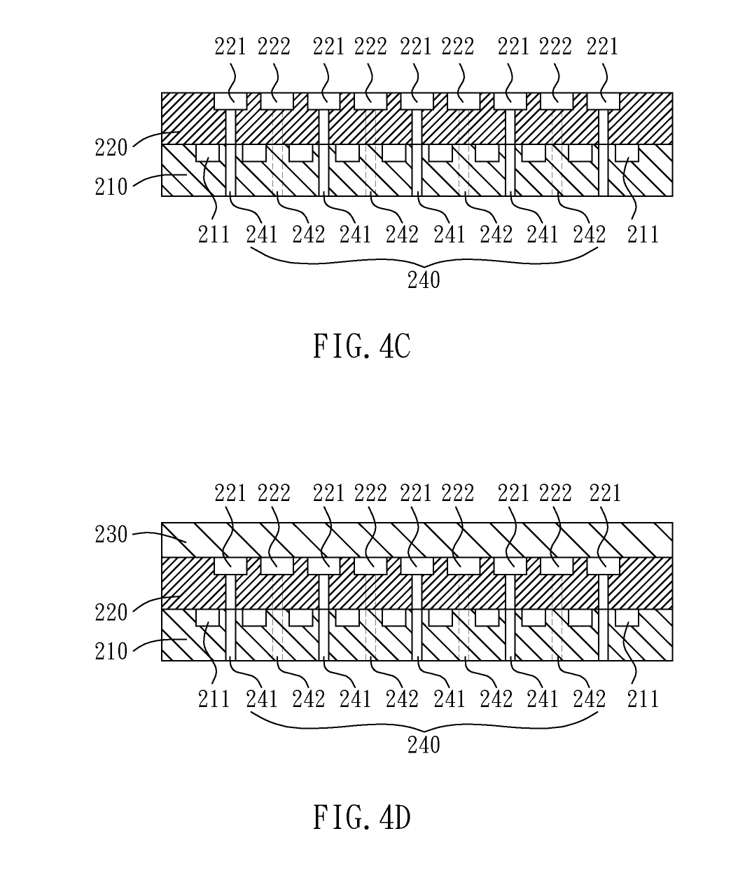

FIGS. 4A-4D show the making steps of the showerhead 200 shown in FIG. 3A. Referring to FIG. 4A, a bottom plate 210 is provided. The bottom plate 210 includes a plurality of cooling channels 211. Then, referring to FIG. 4B, a channel plate 220 is provided. The channel plate 220 includes a first trench area 221 and a second trench area 222. The channel plate 220 is coupled to the bottom plate 210, wherein a soldering process, such as a high temperature soldering process (hard soldering or brazing), is performed for sealing the clearances between the channel plate 220 and the bottom plate 210.

Referring to FIG. 4C, a plurality of gas holes 240 are formed on the bottom plate 210 and the channel plate 220. The gas holes 240 includes at least one first gas hole 241 and at least one second gas hole 242, wherein the first gas hole 241 is connected with the first trench area 221, the second gas hole 242 is connected with the second trench area 222.

In this embodiment, the gas holes 240 are formed on the bottom plate 210 and the channel plate 220 by a mechanical process, wherein the mechanical process can include many kinds of processing methods, such as machining, electric discharge machining, or any other processing method. Any processing method which is capable of forming the gas holes 240 on the bottom plate 210 and the channel plate 220 is possible to be used. Different processing methods should be considered based on the real conditions. Although the mechanical process is used in this embodiment, the gas holes 240 can also be formed on the bottom plate 210 and the channel plate 220 by a chemical process or another processing method. Finally, referring to FIG. 4D, a top plate 230 is provided and assembled to the channel plate 220 so as to finish the making steps of the showerhead 200.

In this embodiment, the gas holes 240 are formed after the step of coupling the channel plate 220 to the bottom plate 210. However, the gas holes 240 can be formed on the bottom plate 210 and the channel plate 220 respectively before the step of coupling the channel plate 220 to the bottom plate 210.

According to the showerhead of the present invention, the gas holes are formed on the bottom plate and the channel plate. There is no need to use gas tubes. Different process gases will not be mixed within the showerhead. The leakage caused by clearances between the gas tubes and the bottom portion is also avoided. Therefore, the showerhead has better ability for bearing high temperature, thermal cycling, and corrosion caused by reaction gases. Thus, the showerhead has longer lifetime, and the cooling fluid will not leak into the inside of the reaction chamber.

Although specific embodiments have been illustrated and described, it will be appreciated by those skilled in the art that various modifications may be made without departing from the scope of the present invention, which is intended to be limited solely by the appended claims.

What is claimed is:

1. A showerhead, comprising:
a bottom plate, said bottom plate having a plurality of cooling channels and a plurality of gas holes, wherein said gas holes comprises at least one first gas hole and at least one second gas hole;
a channel plate, said channel plate comprising a first trench area and a second trench area, wherein said first gas hole is connected with said first trench area, said second gas hole is connected with said second trench area; and
a top plate, wherein said top plate is coupled to said channel plate.

2. The showerhead according to claim 1, wherein said gas holes are formed on said bottom plate and said channel plate by a mechanical process or a chemical process.

3. The showerhead according to claim 1, wherein said bottom plate is coupled to said channel plate by a brazing process.

4. The showerhead according to claim 1, wherein said first trench area comprises a first comb shape, said second trench area comprises a second comb shape, said first comb shape interlaces said second comb shape.

5. The showerhead according to claim 1, wherein said first gas hole is surrounded by said second gas holes.

6. A method for making a showerhead, comprising:
providing a bottom plate, said bottom plate having a plurality of cooling channels;
providing a channel plate, said channel plate comprising a first trench area and a second trench area;
coupling said channel plate to said bottom plate;
forming a plurality of gas holes, wherein said gas holes comprises at least one first gas hole and at least one second gas hole, said first gas hole is connected with said first trench area, said second gas hole is connected with said second trench area; and
providing and assembling a top plate, wherein said top plate is coupled to said channel plate.

7. The method for making a showerhead according to claim 6, wherein said first gas hole is surrounded by said second gas holes.

8. The method for making a showerhead according to claim 6, wherein said gas holes are formed on said bottom plate and said channel plate by a mechanical process or a chemical process.

9. The method for making a showerhead according to claim 6, wherein said bottom plate is coupled to said channel plate by a brazing process.

10. A method for making a showerhead, comprising:
providing a bottom plate, said bottom plate having a plurality of cooling channels and a plurality of gas holes, wherein said gas holes comprises at least one first gas hole and at least one second gas hole;
providing a channel plate, said channel plate comprising a first trench area and a second trench area;
coupling said channel plate to said bottom plate, wherein said first gas hole is connected with said first trench area, said second gas hole is connected with said second trench area; and
providing and assembling a top plate, wherein said top plate is coupled to said channel plate.
